(19) United States
(12) Patent Application Publication
(10) Pub. No.: US 2004/0241596 A1
(43) Pub. Date: Dec. 2, 2004

(54) Method of forming resist patterns and method of producing semiconductor device

(76) Inventors: Yuko Yamaguchi, Kanagawa (JP); Atsushi Someya, Kanagawa (JP); Hiroshi Kagotani, Kanagawa (JP); Kenichi Oyama, Kanagawa (JP); Ryoji Watanabe, Kanagawa (JP)

Correspondence Address: ROBERT J. DEPKE LEWIS T. STEADMAN, HOLLAND & KNIGHT LLC, 131 SOUTH DEARBORN, 30TH FLOOR, CHICAGO, IL, 60603, US

(21) Appl. No.: 10/838,401

(22) Filed: May 4, 2004

(30) Foreign Application Priority Data
May 6, 2003 (JP) P2003-128152

(51) Int. Cl. G03F 7/20

(52) U.S. Cl. 430/394; 430/322; 430/396

(57) ABSTRACT

A method of forming resist patterns able to decrease development defects caused by deposition of a resist film or redeposition of semi-insolubles in a development process and rinse process using general systems, and a method of producing a semiconductor device using the same, having lithographic process for exposing an element formation region of the resist film at the optimal exposure amount able to develop the resist film via a mask and exposing the circumference region other than the element formation region at an exposure amount not exceeding that exposure amount able to develop the resist film, due to these exposing, reducing the difference of developability and thickness after development of the resist film by which the resist patterns are formed, reducing the difference of surface conditions in the element formation region and circumference region, and able to smoothly remove development defects formed at the time of rinsing or by high speed rotation.

### BACKGROUND OF THE INVENTION

1. Field of the Invention

The present invention relates to a method of forming resist patterns and a method of producing a semiconductor device, more particularly relates to a method of forming resist patterns by photolithography in the production of a semiconductor device and a method of producing a semiconductor device using the same.

2. Description of the Related Art

Semiconductor devices are produced using photolithography for forming the device circuits. “Photolithography” is the process of coating the surface of a glass substrate, semiconductor substrate, or other plate-shaped object with an antireflection film material, a resist, or other organic composition, prebaking it to form a film, then exposing, heat treating, and developing the film to form resist patterns.

Recently, LSIs have been made rapidly higher in integration. The line width processed in photolithography has also been steadily reduced. Various approaches have been tried out to realize greater miniaturization in photolithography from the points of the resist material, antireflection film material, and other additional process materials, the exposure method, exposure system, coater developer method and apparatus, etc.

For example, the method of using a short wavelength light source of an exposure wavelength effective for increased miniaturization, that is, a KrF excimer laser of 248 nm, ArF excimer laser of 193 nm, or other deep ultraviolet rays, X-rays, or electron beams, as the exposure light source has been proposed.

In the production of a semiconductor integrated circuit, improvement of the yield is extremely important in view of the productivity. One of the factors reducing the yield is the defects in pattern formation occurring when forming patterns by photolithography. Defects in pattern formation are caused by foreign matter in the resist film or at the surface thereof, deterioration of the resist due to floating chemicals in the clean room environment, coating defects of the resist material or anti-reflection film material, and development defects.

“Development defects” specifically are scum and bridging in resist for line and space, and aperture defects of resist for contact hole. These development defects can be classified into various types. Among them, defects due to residue after development are typical.

Development defects caused by residue are caused by insufficient wetting of the surface of the resist film with a development solution mainly included of water when wetting the development solution on the surface and therefore insufficient dissolution of the exposure parts by the development solution and by substances insoluble in the development solution redepositing on the surface of the resist patterns during rinsing after development. In particular, along with increased miniaturization, resist materials of increasingly diversified compositions are being used for obtaining the desired dimensions and shapes of patterns. As a result, not only the solubility in the developer, but also detailed conditions of the development process, the system environment, exposure area density, and various other factors influence each other. The occurrence and degree of defects are changing as a result.

Various studies have been made to solve these problems. For example, Japanese Patent No. 3320402 discloses a method of pattern formation having coating a chemically amplified photoresist film with a composition for reducing development defects, making the surface hydrophilic, then exposing and developing it to form the resist patterns. It proposes a method and a composition making the reduction of the resist after development greater than when not coating the composition for reducing development defects so as to avoid deterioration of the pattern shapes and prevent development defects.

Japanese Unexamined Patent Publication (Kokai) No. 9-246166 discloses to treat a resist by plasma to change the wettability of the development solution on the surface of the resist and decrease development defects. As methods for improving the wettability of the development solution to prevent development defects, there are also the method of adding a surfactant to the development solution or rinse solution and the method of forming a surface coating film for improving the wettability of the development solution.

The method disclosed in Japanese Patent No. 3320402 is one means for decreasing development defects, but suffers from a few problems from the viewpoint of the increase of the number of nozzles or steps of the treatment process and the throughput due to the addition of other materials to the general process.

The method disclosed in Japanese Unexamined Patent Publication (Kokai) No. 9-246166 has the problems of introduction of a system for plasma treatment and decreased throughput. Further, when improving the wettability of the development solution to prevent development defects by adding a surfactant or forming a surface coating film, the effect of decreasing the defects will differ depending on the materials of the resists or the surfactant. Therefore, careful selection of the materials and optimization of their affinity become necessary. This causes an increase in costs of the materials.

### SUMMARY OF THE INVENTION

An object of the present invention is to provide a method of forming resist patterns able to decrease development defects caused by deposition of the resist film or redeposition of semi-insolubles in a development process and rinse process using a general system and a method of producing a semiconductor device using the same.

To achieve the above object, according to a first aspect of the invention, there is provided a method of forming resist patterns having the steps of forming a resist film on a substrate, exposing an element formation region of the resist film at a first exposure amount able to develop the resist film via a mask, exposing an unexposed region other than the element formation region of the resist film at a second exposure amount not exceeding the exposure amount able to develop the resist film, and developing the resist film.

In the above method of forming resist patterns of the present invention, the first exposure step performs exposure via the mask at a first exposure amount able to develop the resist film. At that time, the element formation region maintains developability enabling the resist film to form predetermined patterns. All regions however are at least slightly exposed.

Therefore, the second exposure step exposes the unexposed region other than the element formation region in the resist film at a second exposure amount not exceeding the exposure amount enabling development of the resist film.

Due to this, the region other than the element formation region is exposed to an extent where it is developed and accordingly the difference of the surface conditions of the element formation region and the other region is reduced.

As a result, even if the resist film is deposited or semi-insolubles are produced in the development step, they are easily removed from the substrate in the subsequent rinsing step.

To achieve the above object, according to a second aspect of the present invention, there is provided a method of producing a semiconductor device having the steps of forming a resist film on a substrate, exposing an element formation region of the resist film at a first exposure amount able to develop the resist film via a mask, exposing an unexposed region other than the element formation region of the resist film at a second exposure amount not exceeding the exposure amount able to develop the resist film, and developing the resist film.

In the above method of producing a semiconductor device of the present invention, the first exposure step performs exposure via the mask at a first exposure amount able to develop the resist film. At that time, the element formation region maintains developability enabling the resist film to form predetermined patterns. All regions however are at least slightly exposed.

Therefore, the second exposure step exposes the unexposed region other than the element formation region in the resist film at a second exposure amount not exceeding the exposure amount enabling development of the resist film.

Due to this, the region other than the element formation region is exposed to an extent where it is developed and accordingly the difference of the surface conditions of the element formation region and the other region is reduced.

As a result, even if the resist film is deposited or semi-insolubles are produced in the development step, they are easily removed from the substrate in the subsequent rinsing step.

According to the present invention, it is possible to decrease development defects caused by deposition of the resist film or redeposition of semi-insolubles in a development process and rinse process using a general system.

### BRIEF DESCRIPTION OF THE DRAWINGS

These and other objects and features of the present invention will become more apparent from the following description of preferred embodiments given with reference to the accompanying drawings, in which:

FIGS. 1A to 1F are cross-sectional views for explaining the general procedure of an overall lithographic process to which the method of forming resist patterns according to an embodiment of the present invention is applied;

FIGS. 2A to 2C are cross-sectional views for explaining the general procedure of an overall lithographic process to which the method of forming resist patterns according to an embodiment of the present invention is applied;

FIGS. 3A and 3B are cross-sectional views of the configuration of a mask used for forming resist patterns according to an embodiment of the present invention, herein FIG. 3A shows a binary mask and FIG. 3B shows a half tone phase shift mask;

FIGS. 4A and 4B are views for explaining a first exposure step in the method of forming resist patterns according to an embodiment of the present invention;

FIGS. 5A and 5B are views for explaining a second exposure step in the method of forming resist patterns according to an embodiment of the present invention;

FIGS. 6A to 6C are cross-sectional views for explaining development and rinsing steps in the method of forming resist patterns according to an embodiment of the present invention;

FIGS. 7A and 7B are views for explaining the effect of the method of forming resist patterns according to an embodiment of the present invention; and

FIGS. 8A and 8B are cross-sectional views of configurations of other masks able to be used for the method of forming resist patterns according to an embodiment of the present invention, wherein FIG. BA shows a stencil mask and FIG. 8B shows a membrane mask.

### DESCRIPTION OF THE PREFERRED EMBODIMENTS

Next, preferred embodiments of a method of forming resist patterns and a method of producing a semiconductor device will be explained with reference to the drawings.

### First Embodiment

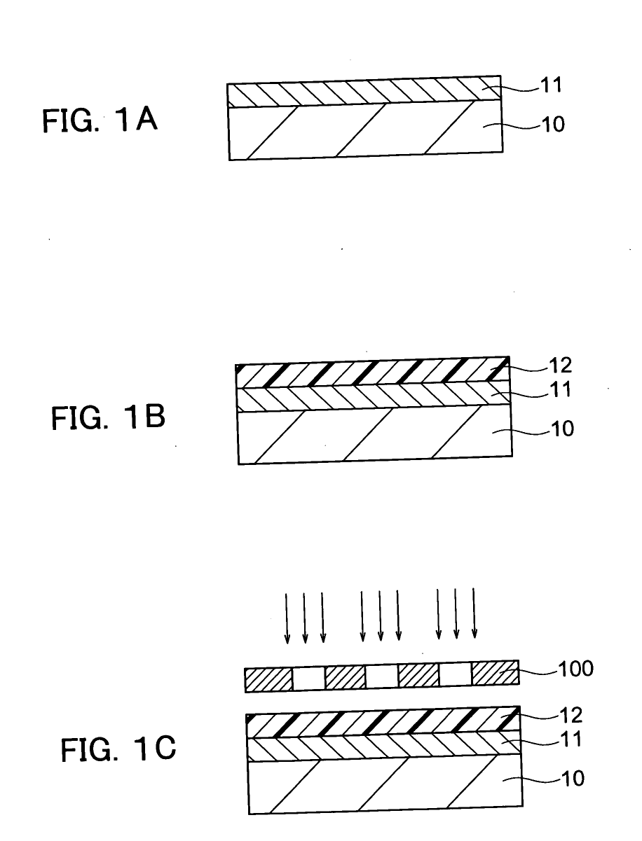

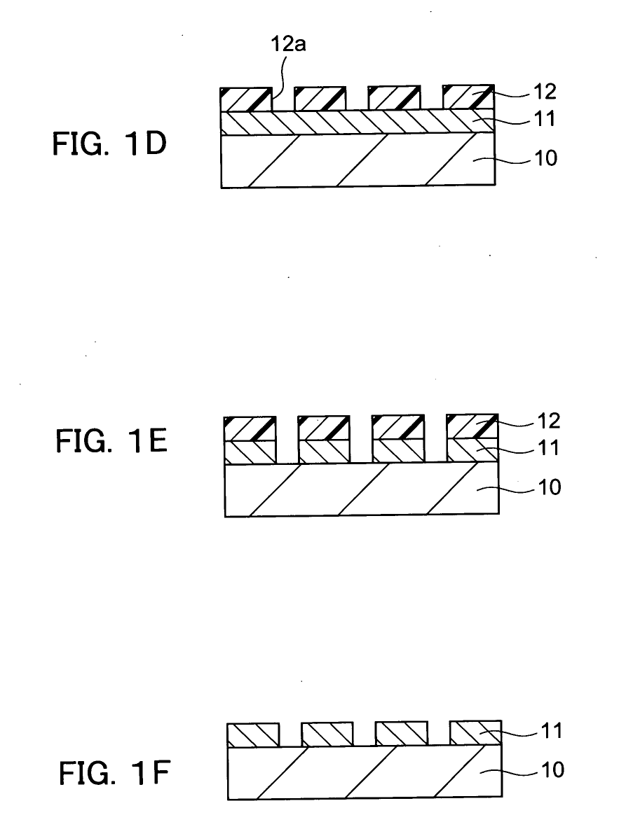

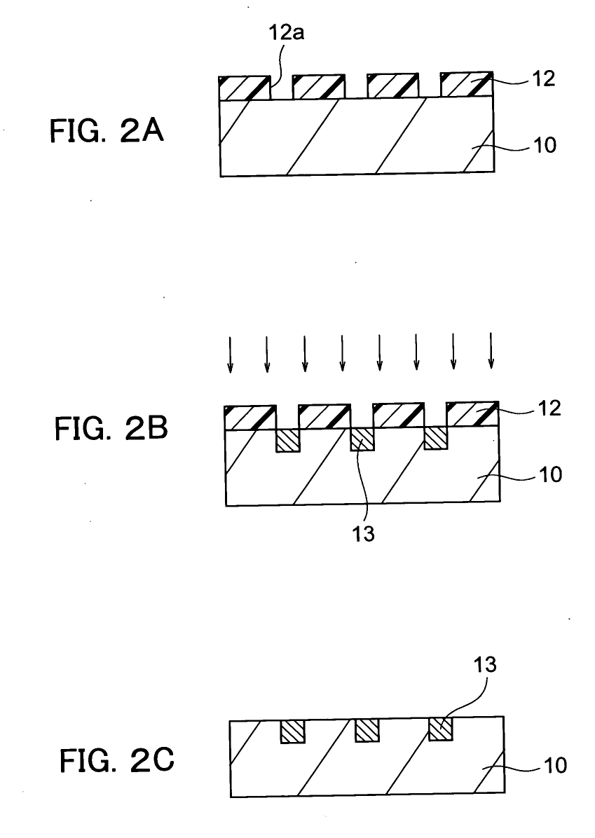

First, the general procedure of the overall lithographic process to which the method of forming resist patterns according to the present embodiment is applied will be explained with reference to FIGS. 1A to 1F and FIGS. 2A to 2C.

A substrate 10 formed on its surface with a processing film 11 shown in FIG. 1A is coated with a resist formed by a photosensitive polymer material dissolved in an organic solvent. Then, the excess organic solvent is dried off by prebaking to form a resist film 12 as shown in FIG. 1B.

As shown in FIG. 1C, ultraviolet light, an electron beam, X-rays, etc. is irradiated via a mask 100 so as to partially focus energy on the resist film 12 for exposure. After exposure, the unnecessary parts of the resist film 12 are dissolved off by a development solution, then the film is rinsed by a rinse solution of pure water. As a result, as shown in FIG. 1D, the resist film 12 is formed with apertures 12a to form resist patterns.

The above steps of coating the resist, exposure, development, and rinsing are referred to as the “lithographic process”.

After the resist pattern is formed by the lithography, as shown in FIG. 1E, the processing film 11 is etched using the resist film 12 as a mask. Finally, the unnecessary resist film 12 is removed. Due to this, as shown in FIG. 1F, patterns are formed at the processing film 11. The patterns of the processing film 11 are used to form a semiconductor device.

The resist patterns may be used for ion implantation to a substrate as well.

Specifically, as shown in FIG. 2A, similar to above, the substrate 10 is formed with a resist film 12 of the desired patterns by lithography, then, as shown in FIG. 2B, and the substrate 10 is implanted with ions using the resist film 12 as a mask to form an impurity region 13. Finally, as shown in FIG. 2C, the unnecessary resist film 12 is removed, whereby an impurity region 13 constituted by a source/drain region of a transistor etc. is formed.

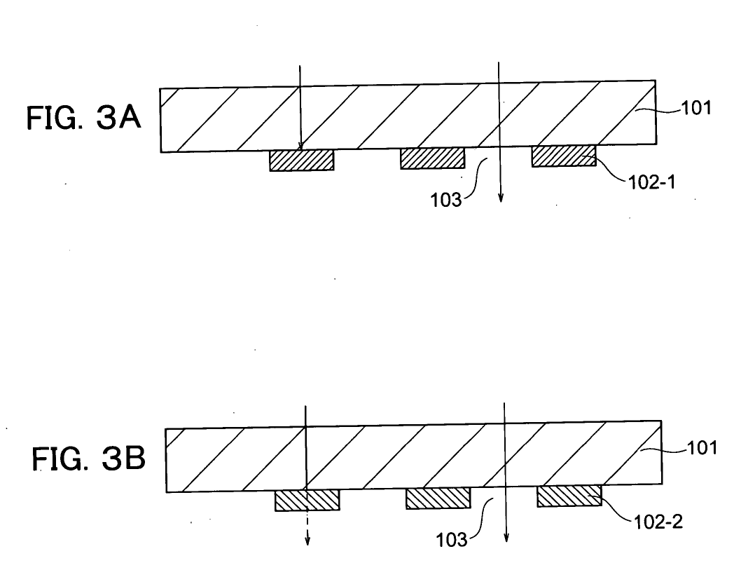

FIGS. 3A and 3B show examples of the mask 100 used in the exposure step shown in FIG. 1C in the above lithographic process.

The mask shown in FIG. 3A is formed by a glass or other transparent substrate 101 on which shield parts are formed by chrome or another metal shield film 102-1 high in shieldability. This is called a “binary mask”. In a binary mask, transparent parts 103 where the shield film 102-1 is not formed pass the light, while the shield, parts do not pass the light.

On the other hand, in lithography using a short wavelength light ArF excimer laser as an exposure light source, the half tone phase shift mask shown in FIG. 3B is used. The half tone phase shift mask shown in FIG. 3B is formed by a glass or other transparent substrate 101 on which shield parts are formed by a semi-transparent film 102-2 of chromium fluoride (CrF) etc. In a half tone phase shift mask, even the shield parts formed by the semi-transparent film 102-2 have a transmittance of about 6% and therefore pass light, though slightly. The light passed though the shield parts is opposite in phase from the light passed though the transparent parts 103. Therefore, at the boundary parts, a drop in light intensity occurs due to the phase inversion. Therefore, it is possible to suppress spreading of the edges of the light intensity profile and therefore possible to improve the resolution.

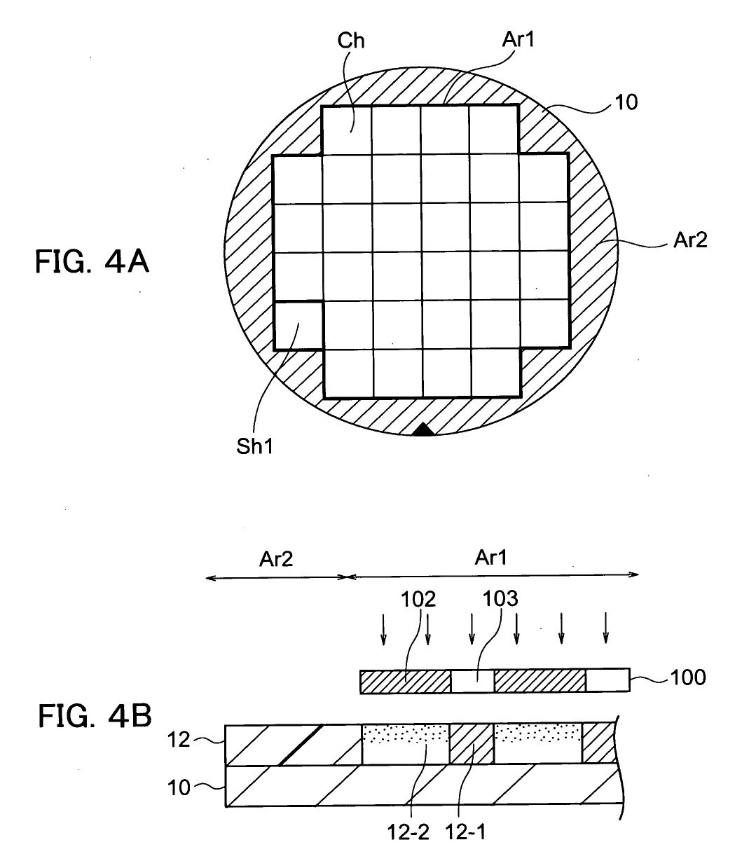

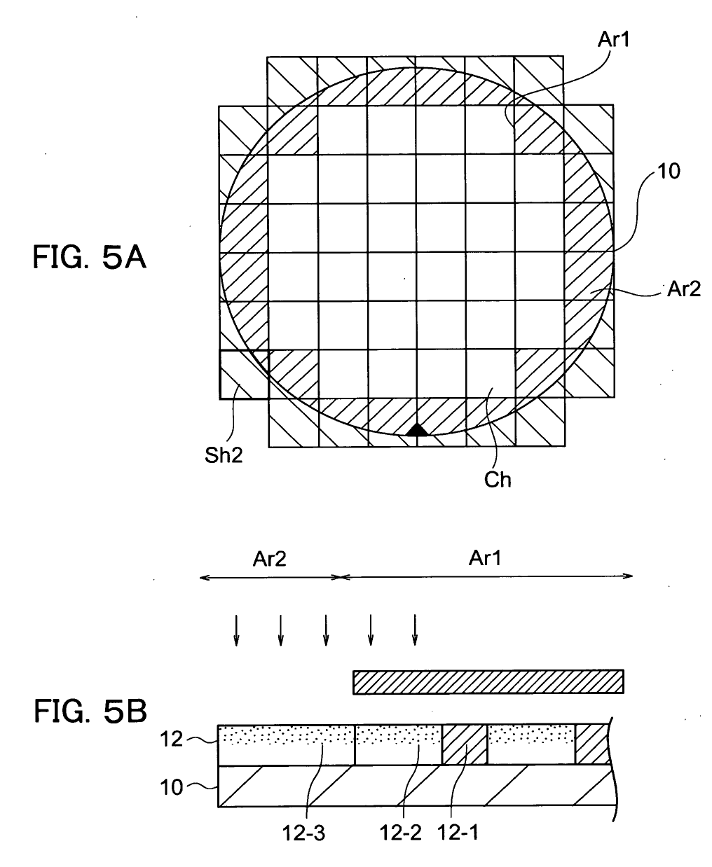

In the lithographic process having the above steps of coating the resist, exposure, development, and rinsing, the present embodiment incorporates special features in the exposure step as explained below. Below, as an example, a case of using an ArF excimer laser as the exposure light source, using a half tone phase shift mask as the mask, and using a positive-type resist as the resist film will be explained with reference to FIGS. 4A and 4B and FIGS. 5A and 5B.

As shown in FIG. 4A, a substrate 10 formed by a semiconductor wafer etc. to be exposed may be mainly divided into an element formation region Ar1 for forming a plurality of semiconductor chips Ch and a surrounding portion Ar2 outside of the element formation region Ar1 where no semiconductor chips Ch are formed. The above element formation region Ar1 becomes the exposure area in the exposure step.

With exposure using an ArF excimer laser or other deep ultraviolet rays, the region corresponding to one semiconductor chip Ch is defined as one shot region Sh1 (region irradiated by one exposure). By repeatedly moving the substrate 10 and exposing shot regions Sh1, all of element formation region Ar1 of the substrate 10 is exposed. Due to the first exposure step, as shown in FIG. 4B, the regions 12-1 of the resist film corresponding to the transparent parts 103 of the mask are irradiated at the exposure amounts required for development. The regions 12-2 of the resist film corresponding to the shield parts 102 of the mask are irradiated by light as well though by just about 6% of exposure amount of the regions 12-1. However, since the exposure amount to the regions 12-2 is sufficiently smaller than the exposure amount required for development of the resist film 12, the resist film 12 is not developed there.

After exposing the element formation region Ar1, as shown in FIG. 5A, the circumference region Ar2 of the substrate 10 is exposed. The circumference region Ar2 is exposed at each shot regions Sh2, but the exposure amount is made an extent for no resolution at the later development step. Preferably, to make the exposure amount the same as the regions 12-2 of the resist film 12 corresponding to the shield parts 102 of the mask, the exposure amount to the resist film 12 at the circumference region Ar2 is made the optimal exposure amount in the first exposure step multiplied with the transmittance of the shield parts 102 of the mask.

Due to the second exposure step, as shown in FIG. 5B, the exposure amounts of the regions 12-2 of the resist film in the element formation region Ar1 and the circumference region Ar2 (12-3) approach each other, so the difference of the surface conditions of the two regions in the resist film is decreased. As factors of the surface condition of the resist film, the surface tension, surface roughness, etc. may be mentioned.

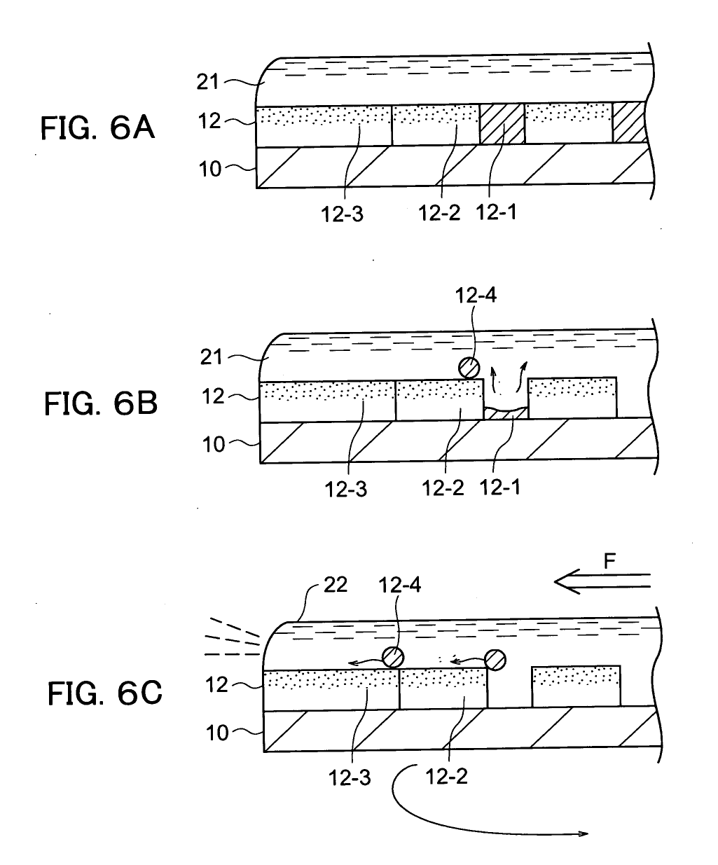

Next, as shown in FIG. 6A, a not shown spray nozzle is used to supply the development solution 21 to build up the development solution 21 on the substrate 10 formed with the resist film 12 and keep it there by surface tension.

As shown in FIG. 6B, in the case of using a positive-type resist as the resist film 12, the regions 12-1 of the resist film sufficiently irradiated with light are dissolved by the development solution 21, but insolubles 12-4 not able to be dissolved by the development solution 21 occur at some parts.

Finally, as shown in FIG. 6C, after development, the substrate 10 is rotated and rinsed by a rinse solution 22 of the pure water, whereby the insolubles 12-4 are conveyed to the circumference of the substrate 10 due also to the centrifugal force F of rotation shown as the arrow and removed to the outside of the substrate 10. The exposure amounts at the regions 12-2 of the resist film in the element formation region Ar1 and the circumference region Ar2 (12-3) approach each other and the difference of the surface conditions of the resist film of the two regions is reduced, so at the rinsing step, development defects caused by the insolubles 12-4 can smoothly be removed from the substrate 10 by rinsing or high speed rotation.

Next, the effects of the method of forming resist patterns according to the present embodiment will be explained with reference to examples and comparative examples.

### COMPARATIVE EXAMPLE 1

As Comparative Example 1, an 8-inch wafer was formed with an antireflection film AR19 (Shipley Company) of a thickness of 85 nm. This in turn was coated with an ArF acrylic-based resist (JSR Corporation) to a thickness of 300 nm. The thus coated wafer was prebaked at 130° C. for 90 seconds, then exposed by an ArF scanner PASS 5500/1100 (ASM Lithography Corporation) using a suitable mask at 15 mJ/cm². Next, the wafer was post-exposure baked at 150° C. for 90 seconds, then developed by an NMD-3 (Tokyo Ohka Kogyo Co., Ltd.) for 30 seconds, then rinsed by pure wafer to form the patterns. In Comparative Example 1, a coater developer ACT-8 (Tokyo Electron) was used for coating the material, baking, development, and rinsing to form the Sample Substrate 1.

### EXAMPLE OF INVENTION

As an example of the invention, an 8-inch wafer was formed with an antireflection film AR19 (Shipley Company) of a thickness of 85 nm. This in turn formed was coated with an ArF acrylic-based resist (JSR Corporation) to a thickness of 300 nm. The thus coated wafer was prebaked at 130° C. for 90 seconds, then exposed by an ArF scanner PASS 5500/1100 (ASM Lithography Corporation) using a suitable mask by 15 mj/cm². Next, the circumference portion other than the shot regions was exposed by 1 mJ/cm². Next, the wafer was post-exposure baked at 150° C. for 90 seconds and developed by an NMD-3 (Tokyo Ohka Kogyo Co., Ltd.) for 30 seconds, then rinsed by pure wafer to form the patterns. In this example, a coater developer ACT-8 (Tokyo Electron) was used for coating the material, baking, development, and rinsing to form the Sample Substrate 2.

### COMPARATIVE EXAMPLE 2

As Comparative Example 2, an 8-inch wafer was formed with an antireflection film AR19 (Shipley Company) of a thickness of 85 nm. This in turn was coated with an ArF acrylic-based resist (JSR Corporation) to a thickness of 300 nm. The thus coated wafer was prebaked at 130° C. for 90 seconds, then fully exposed by an ArF scanner PASS 5500/1100 (ASM Lithography Corporation) using a suitable mask at 15 mJ/cm² including the wafer circumference region. Next, the wafer was post-exposure baked at 150° C. for 90 seconds, then developed by an NMD-3 (Tokyo Ohka Kogyo Co., Ltd.) for 30 seconds, then rinsed by pure wafer to form the patterns. In Comparative Example 2, a coater developer ACT-8 (Tokyo Electron) was used for coating the material, baking, development, and rinsing to form the Sample Substrate 3.

### Evaluation Results

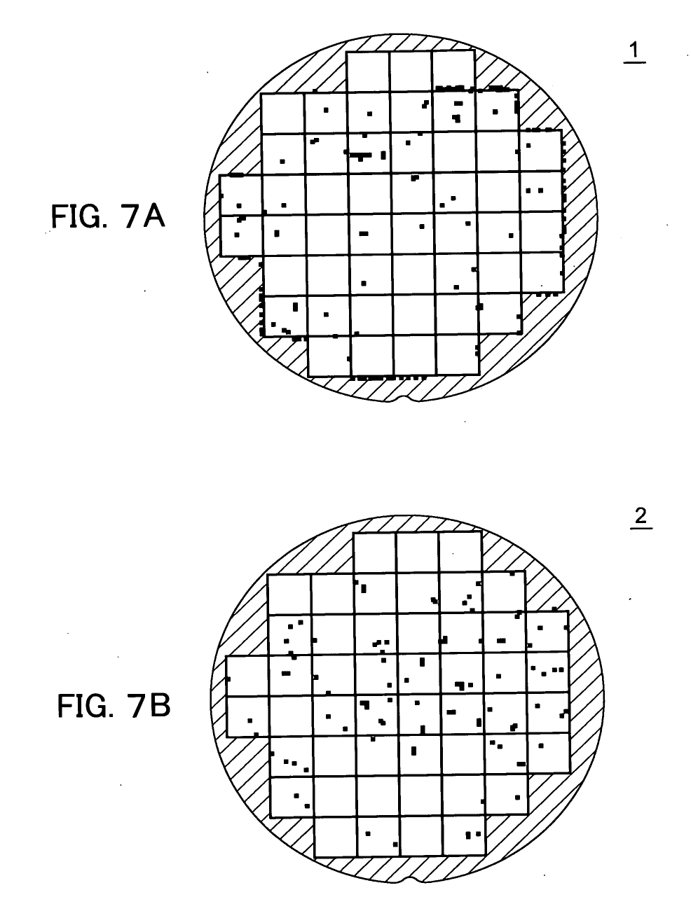

The sample substrates were inspected for defects using a defect inspection system KLA S2132. FIG. 7A shows the results of inspection of defects of the Sample substrate 1, while FIG. 7B shows the results of inspection of defects of the Sample Substrate 2.

As shown in FIG. 7A, the Sample Substrate 1 of comparative Example 1 without exposure at the circumference of the substrate had 93 development defects. In FIG. 7A, the other defects were quasi-defects not affecting the substrate characteristics. The development defects were mainly at the boundary parts of the element formation region and the circumference region.

On the other hand, as shown in FIG. 7B, the Sample Substrate 2 of the example of the invention with exposure at the circumference of the substrate had two development defects so was decreased in number of defects. In FIG. 7B, the other defects were quasi-defects. Since Comparative Example 2 with full exposure of the circumference of the wafer also had two development defects, it is learned that the present embodiment can realize a defect level of the same extent as full exposure without pattern formation.

With the method of forming resist patterns and the method of producing a semiconductor device according to the present embodiment, in the lithographic process, the resist film 12 at the element formation region Ar1 of the substrate 10 is exposed at the optimal exposure amount able to develop the resist film 12 (first exposure amount) via the mask 100, then the resist film 12 at the circumference region Ar2 other than the element formation region Ar1 is exposed at an exposure amount not exceeding the exposure amount able to develop the resist film 12.

The boundary parts of the circumference region Ar2 and the element formation region Ar1 of the substrate are susceptible to defects. In the case of deposition type development defects, it may be considered to extend the rinse time or adjust the rinse speed so as to spin them off by physical force and reduce the development defects. However, there are limits to the extension of the rinse time in view of the throughput. Further, while there is an effect of reduction at the center part of the substrate, it is difficult to reduce the development defects accumulated at the boundary of the circumference region and the element formation region.

Therefore, in the present embodiment, even the circumference region of the substrate other than the actually required element formation region is exposed to an extent not resolving by the development solution. Due to this, the development defects accumulated at the boundary of the circumference region and the element formation region are greatly decreased. This is because, as explained above, the circumference region of the substrate is lightly exposed so as to reduce the difference of developability of the resist film between the element formation region Ar1 later forming the resist patterns and the circumference region and the difference of the thickness after development and to reduce the difference of the surface conditions of the resist film at the element formation region and the circumference region. As a result, any formed development defects can be smoothly spun off when rinsing or by high speed rotation.

In this way, according to the method of forming resist patterns according to the present embodiment, it is possible to decrease development defects caused by deposition of the resist film or redeposition of semi-insolubles in the development and rinsing steps using an ordinary system.

Therefore, the reliability of a semiconductor device produced by etching or ion implantation using the resist patterns can be improved.

Although an example using an ArF excimer laser or other deep ultraviolet rays was explained above, the invention can also be applied to a lithography process using deep ultraviolet rays of another wavelength region or X-rays or electron beams as the exposure light source.

For example, lithography using electron beams includes lithography projecting a charged particle beam passed through a mask on a wafer by an electron-ion optical system such as electron projection lithography (EPL) and ion projection lithography (IPL) and lithography transferring mask patterns to a wafer arranged close under a mask without going through an optical focus system such as proximity electron lithography (PEL).

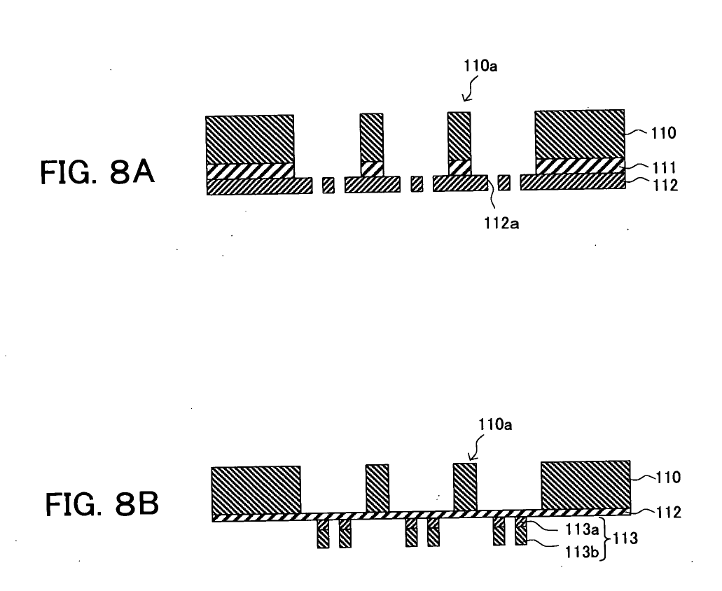

In the above mask, the patterns to be transferred are arranged at a thin film region (membrane) of a thickness of about 10 nm to 10 μm. A mask with the transfer patterns formed by apertures of the membrane is called a stencil mask. This mask is for example disclosed in Japanese Unexamined Patent Publication No. 2002-231599, No. 2002-270496, and No. 2002-343710. A mask with the transfer patterns formed by metal thin film or another member for scattering a charged particle beam is called a scatter membrane mask. FIGS. 8A and 8B show examples of cross-sectional configurations of a stencil mask and scatter membrane mask.

FIG. 8A is a cross-sectional view of a stencil mask. The stencil mask shown in FIG. 8A is formed by a support 110 formed with a reinforcing layer 111 and a membrane (thin film) 112. The support 110 and the reinforcing layer 111 are processed to form struts 110a. The thin film 112 at the pattern formation regions defined by the struts 110a are formed with aperture patterns 112a. The thickness of the reinforcing layer 111 is 10 μm and the thickness of the thin film 112 is 500 nm, for example.

FIG. 8B is a cross-sectional view of a scatter membrane mask. The scatter membrane mask shown in FIG. 8B is formed by a support 110 formed with a thin film 112. The support 110 is processed to form struts 110a. Note that, similarly to FIG. 8A, a reinforcing layer 111 may also be formed between the support 110 and the thin film 112. The sections of the thin film 112 surrounded by the struts 110a are formed with scatter patterns 113 comprised of a chrome layer 113a and a tungsten layer 113b. For example, the thickness of the thin film 112 is 500 nm, the thickness of the chrome layer 113a is 10 nm, and the thickness of the tungsten film 113b is 50 nm.

The present invention can also be applied to the case of forming resist patterns through the mask shown in FIG. 8A or 8B using an electron beam as an exposure light source at the time of exposure as shown in FIG. 1C.

Note that the present invention is not limited to the materials or numerical values described in the above explanation of the embodiments. For example, the invention was explained with reference to the example of use of a positive-type resist as a resist, but a negative-type resist can also be used.

While the invention has been described with reference to specific embodiments chosen for purpose of illustration, it should be apparent that numerous modifications could be made thereto by those skilled in the art without departing from the basic concept and scope of the invention.

What is claimed is:

1. A method of forming resist patterns comprising the steps of:
forming a resist film on a substrate;
exposing an element formation region of said resist film at a first exposure amount able to develop said resist film via a mask;
exposing an unexposed region other than the element formation region of said resist film at a second exposure amount not exceeding the exposure amount able to develop said resist film; and
developing said resist film.

2. A method of forming resist patterns as set forth in claim 1, wherein:
in the step of first exposing, said first exposure is carried out them via said mask having shield patterns having a predetermined transmittance to an exposure beam and
in the step of second exposing, said second exposure is carried out them at said second exposure amount substantially equal to an exposure amount which is defined by multiplying said first exposure amount and said transmittance.

3. A method of producing a semiconductor device comprised of a substrate formed on it with a resist pattern serving as a mask for etching or ion implantation, comprising the steps of:
forming a resist film on a substrate;
exposing an element formation region of said resist film at a first exposure amount able to develop said resist film via a mask;
exposing an unexposed region other than the an element formation region of said resist film at a second exposure amount not exceeding the exposure amount able to develop said resist film; and
developing said resist film.

4. A method of producing a semiconductor device as set forth in claim 3, wherein:
in the step of first exposing, said first exposure is carried out them via said mask having shield patterns having a predetermined transmittance to an exposure beam and
in the step of second exposing, said second exposure is carried out them at said second exposure amount substantially equal to an exposure amount which is defined by multiplying said first exposure amount and said transmittance.
